(19) United States
(12) Patent Application Publication
(10) Pub. No.: US 2013/0248994 A1
(43) Pub. Date: Sep. 26, 2013

(54) POWER SEMICONDUCTOR DEVICE

(71) Applicant: Hideaki NINOMIYA, Hyogo-ken (JP)

(72) Inventor: Hideaki NINOMIYA, Hyogo-ken (JP)

(73) Assignee: Kabushiki Kaisha Toshiba, Tokyo (JP)

(21) Appl. No.: 13/600,656

(22) Filed: Aug. 31, 2012

(30) Foreign Application Priority Data
Mar. 23, 2012 (JP) 2012-068431

(51) Int. Cl. H01L 29/78; H01L 27/06

(52) U.S. Cl. 257/334; 257/330; 257/E29.262; 257/E27.016

(57) ABSTRACT

A power semiconductor device includes a first semiconductor layer of a first conductivity type, a second semiconductor layer of a second conductivity type, a third semiconductor layer of the first conductivity type, a fourth semiconductor layer of the second conductivity type. The first semiconductor layer has a first surface and a second surface on opposite side from the first surface and includes a first trench extending from the first surface. The gate electrode is provided via a gate insulating film on the first semiconductor layer, on the second semiconductor layer, and on the third semiconductor layer in the first trench. The fourth semiconductor layer is extending from the first surface of the first semiconductor layer to the second surface side farther than the first trench. A conductor is provided via an insulating film in the fourth semiconductor layer. The conductor is electrically connected to the gate electrode.

### CROSS-REFERENCE TO RELATED APPLICATION

This application is based upon and claims the benefit of priority from the prior Japanese Patent Application No.2012-068431, filed on Mar. 23, 2012; the entire contents of which are incorporated herein by reference.

### FIELD

Embodiments described herein relate generally to a gate insulated power semiconductor device.

### BACKGROUND

In insulated gate power semiconductor devices such as IGBT (insulated gate bipolar transistor) and MOSFET (metal oxide semiconductor field effect transistor), reduction of turn-on loss is desired. However, reduction of turn-on loss results in sharp decrease of emitter-collector voltage of the insulated gate power semiconductor device (or source-drain voltage in the case of MOSFET). Thus, noise is generated in the gate. The problem is that this results in the destruction of the insulated gate power semiconductor device. One method for reducing turn-on loss while suppressing this problem is to decrease the gate resistance built in the gate driving circuit for controlling the gate signal of the insulated gate power semiconductor device, and to increase the gate-emitter capacitance of the insulated gate power semiconductor device (or gate-source capacitance in the case of MOSFET). This gate-emitter (gate-source) capacitance can be increased by an external capacitor. However, this causes the problem of the increased size of the device containing the insulated gate power semiconductor device, the increased cost of the assembly process, and the difference in temperature dependence between the external capacitor and the insulated gate power semiconductor device. Thus, there is demand for increasing the gate-emitter (gate-source) capacitance built in the chip of the insulated gate power semiconductor device.

### BRIEF DESCRIPTION OF THE DRAWINGS

FIG. 1 is a main part schematic sectional view of a power semiconductor device according to a first embodiment.

FIG. 2 is a view showing the time variation of current and voltage at turn-on of a power semiconductor device according to a comparative example.

FIG. 3 is a main part schematic sectional view of a power semiconductor device according to a second embodiment.

FIG. 4 is a main part schematic top view of a power semiconductor device according to a third embodiment.

FIG. 5 is a main part schematic top view of a power semiconductor device according to a fourth embodiment.

FIG. 6 is a main part schematic top view of a power semiconductor device according to a fifth embodiment.

FIG. 7 is a main part schematic top view of a power semiconductor device according to a sixth embodiment.

FIG. 8 is a main part schematic top view of a power semiconductor device according to a seventh embodiment.

### DETAILED DESCRIPTION

A power semiconductor device includes a first semiconductor layer of a first conductivity type, a second semiconductor layer of a second conductivity type, a third semiconductor layer of the first conductivity type, a fourth semiconductor layer of the second conductivity type, a gate electrode, a conductor, a first interlayer insulating film, a second interlayer insulating film, a first electrode, and a second electrode.

The first semiconductor layer has a first surface and a second surface on opposite side from the first surface and includes a first trench extending from the first surface toward the second surface. The second semiconductor is provided in the first surface of the first semiconductor layer, is adjacent to the first trench, and is exposed at a sidewall of the first trench. The third semiconductor layer is selectively provided in a surface of the second semiconductor layer, is adjacent to the first trench, and is exposed at the sidewall of the first trench.

The fourth semiconductor layer is extending from the first surface of the first semiconductor layer to the second surface side farther than the first trench.

The gate electrode is provided via a gate insulating film on the first semiconductor layer, on the second semiconductor layer, and on the third semiconductor layer in the first trench;

The conductor is provided via an insulating film on the fourth semiconductor layer in a second trench extending from a surface of the fourth semiconductor layer into the fourth semiconductor layer. The conductor is electrically connected to the gate electrode;

The first interlayer insulating film is provided on the gate electrode. The second interlayer insulating film is provided on the conductor.

The first electrode is electrically connected to the second surface of the first semiconductor layer. The second electrode is electrically connected to the second semiconductor layer, the third semiconductor layer, and the fourth semiconductor layer. The second electrode is insulated from the gate electrode by the first interlayer insulating film.

Embodiments of the invention will now be described with reference to the drawings. The drawings used to describe the embodiments are schematic for simplicity of description. The shape, dimension, size relation and the like of the components in the drawings do not necessarily need to be realized as shown in actual practice, but can be appropriately modified as long as the effect of the invention is achieved. In this description, the first conductivity type is n-type, and the second conductivity type is p-type. However, these conductivity types can be interchanged. As a semiconductor material, silicon is taken as an example in this description. However, the embodiments are also applicable to compound semiconductors such as SiC and GaN. As an insulating film, silicon oxide is taken as an example in this description. However, other insulators such as silicon nitride and silicon oxynitride can also be used. In the case where the n-type conductivity is denoted by n⁺, n, and n⁻, it is assumed that the n-type impurity concentration is decreased in this order. Likewise, also for p-type, it is assumed that the p-type impurity concentration is decreased in the order of p⁺, p, and p⁻. In describing the insulated gate power semiconductor device, IGBT is taken as an example. However, the embodiments of the invention are also applicable to e.g. MOSFET and IEGT (injection enhanced gate transistor).

### First Embodiment

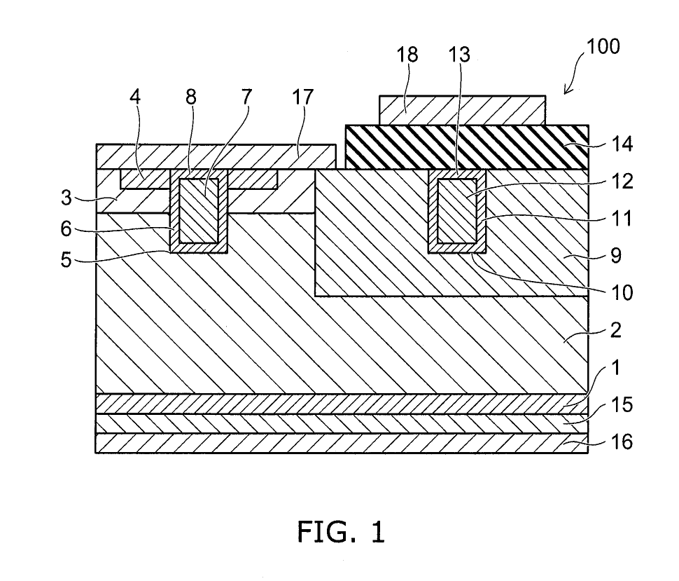

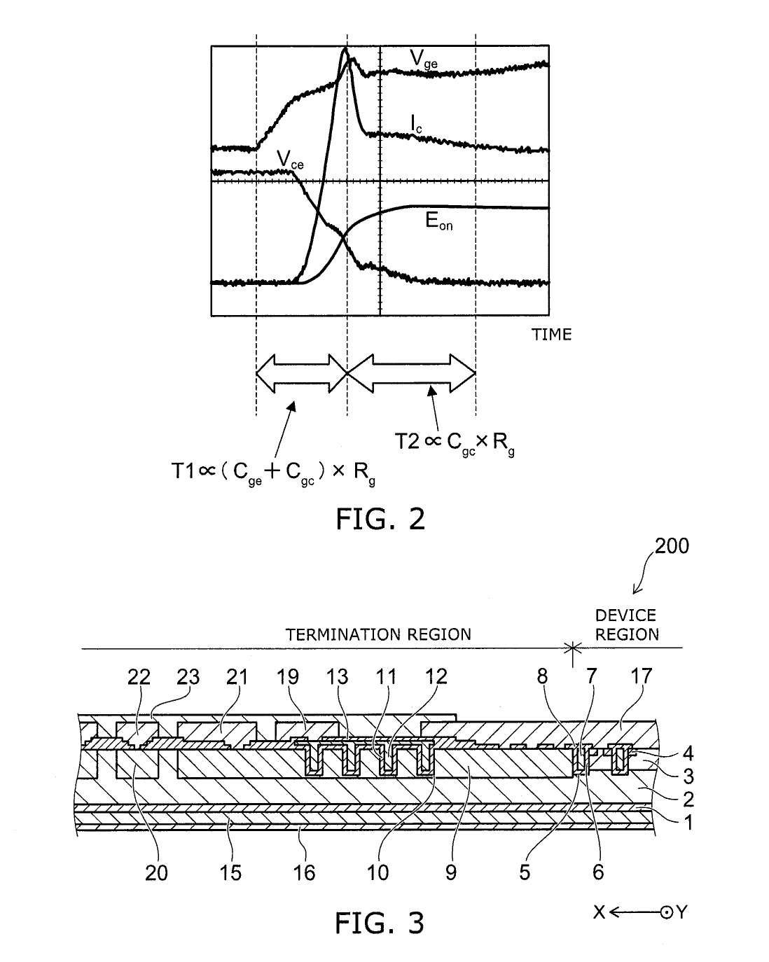

With reference to FIGS. 1 and 2, an IGBT 100 according to a first embodiment of the invention is described. FIG. 1 is a main part schematic sectional view of the IGBT 100 according to the first embodiment. FIG. 2 shows the time variation of current and voltage at turn-on of an IGBT according to a comparative example.

As shown in FIG. 1, the power semiconductor device 100 according to this embodiment includes a p⁺-type collector layer 15, an n⁺-type buffer layer 1, an n⁻-type base layer 2, a first trench 5, a p-type base layer 3, an n⁺-type emitter layer 4, a p⁺-type semiconductor layer 9, a second trench 10, a gate electrode 7, a conductor 12, a first interlayer insulating film 8, a second interlayer insulating film 13, a collector electrode 16, an emitter electrode 17, a field insulating film 14, and a gate pad 18. The p⁺-type collector layer 15, the n⁺-type buffer layer 1, the n⁻-type base layer 2, the p-type base layer 3, the n⁺-type emitter layer 4, and the p⁺-type semiconductor layer 9 are semiconductor layers made of silicon. In this description, it is assumed that n-type and p-type are a first conductivity type and a second conductivity type, respectively. Furthermore, in this description, it is assumed that the collector electrode and the emitter electrode are a first electrode and a second electrode, respectively. In the case of MOSFET, the drain electrode and the source electrode correspond to the first electrode and the second electrode, respectively.

The n⁻-type base layer 2 has a first surface and a second surface on the opposite side from the first surface. On the second surface of the n⁻-type base layer 2, the p⁺-type collector layer 15 is provided via the n⁺-type buffer layer 1. The n-type impurity concentration of the n⁺-type buffer layer 1 is higher than the n-type impurity concentration of the n⁻-type base layer 2.

The first trench 5 is provided in the n⁻-type base layer 2 so as to extend from the first surface toward the second surface of the n⁻-type base layer 2. The p-type base layer 3 is selectively provided in the first surface of the n⁻-type base layer 2. The p-type base layer 3 is adjacent to the first trench 5 and exposed at the sidewall of the first trench 5. The p-type impurity concentration of the p-type base layer 3 is lower than the p-type impurity concentration of the p⁺-type collector layer 15. The n⁺-type emitter layer 4 is selectively provided in the surface of the p-type base layer 3. The n⁺-type emitter layer 4 is adjacent to the first trench 5 and exposed at the sidewall of the first trench 5. The n-type impurity concentration of the n⁺-type emitter layer 4 is higher than the n-type impurity concentration of the n⁻-type base layer 2.

The p⁺-type semiconductor layer 9 extends from the first surface of the n⁺-type base layer 2 to the second surface side farther than the first trench 5. That is, the p⁺-type semiconductor layer 9 is formed from the first surface of the n⁻-type base layer 2 more deeply than the first trench 5. The p-type impurity concentration of the p⁺-type semiconductor layer 9 is higher than the p-type impurity concentration of the p-type base layer 3.

The second trench 10 is provided so as to extend from the surface of the p⁺-type semiconductor layer 9 into the p⁺-type semiconductor layer 9. The second trench 10 extends from the surface of the p⁺-type semiconductor layer 9 toward the second surface of the n⁻-type base layer 2 to the same depth (distance) as the first trench 5. The first trench 5 and the second trench 10 can be integrally formed in the same process. In the case of being formed not in the same process, the second trench 10 may be formed deeper than the first trench 5 as long as the second trench 10 does not protrude from the p⁺-type semiconductor layer 9 into the n⁻-type base layer 2.

A gate insulating film 6 is provided so as to entirely cover the inner wall (bottom surface and sidewall) of the first trench. The gate insulating film 6 is made of e.g. silicon oxide (SiO₂) and formed by thermal oxidation. Instead of thermal oxidation, the CVD (chemical vapor deposition) method can also be used. Furthermore, instead of silicon oxide, for instance, silicon nitride (SiN), silicon oxynitride (SiNO)), or alumina (Al₂O₃) can also be used.

The gate electrode 7 is provided via the gate insulating film 6 on the n⁻-type base layer 2, on the p-type base layer 3, and on the n⁺-type emitter layer 4 in the first trench 5. The gate electrode 7 is formed from e.g. conductive polysilicon.

An insulating film 11 is provided so as to entirely cover the inner wall (bottom surface and sidewall) of the second trench. Like the gate insulating film 6, the insulating film 11 can be made of one of e.g. silicon oxide, silicon nitride, silicon oxynitride, and alumina. In the case of being made of the same material as the gate insulating film 6, the insulating film 11 can be integrally formed in the same process as the gate insulating film 6. As described later, the insulating film 11 can be made of a dielectric having a higher dielectric constant than the gate insulating film 6. For instance, in the case where the gate insulating film 6 is made of silicon oxide, the insulating film 11 can be made of e.g. silicon nitride or alumina. Alternatively, the gate insulating film 6 can be what is called a high-k film made of e.g. hafnium silicate (HfSiO), nitrogen-doped hafnium silicate (HfSiON), nitrogen-doped hafnium aluminate (HfAlON), yttrium oxide (Y₂O₃), or hafnium oxide (HfO₂).

The conductor 12 is provided via the insulating film 11 on the p⁺-type semiconductor layer 9 in the second trench 10. The conductor 12 is electrically connected to the gate electrode 7. Like the gate electrode 7, the conductor 12 can be formed from conductive polysilicon. The conductor 12 can be integrally formed in the same process as the gate electrode 7.

The first interlayer insulating film 8 is provided on the gate electrode 7. In conjunction with the gate insulating film 6, the first interlayer insulating film 8 insulates the gate electrode 7 from the surroundings. The gate electrode 7 is electrically connected to the gate pad 18 by a gate wiring, not shown, via an opening, not shown, of the first interlayer insulating film 8. The second interlayer insulating film 13 is provided on the conductor 12. In conjunction with the insulating film 11, the second interlayer insulating film 13 insulates the conductor 12 from the surroundings. Like the gate insulating film 6, the first interlayer insulating film 8 and the second interlayer insulating film 13 can be formed from one of e.g. silicon oxide, silicon nitride, silicon oxynitride, and alumina.

The collector electrode 16 is provided so as to be electrically connected to the p⁺-type collector layer 15. The collector electrode 16 is electrically connected to the second surface of the n⁻-type base layer 2 via the n⁺-type buffer layer 1. The emitter electrode 17 is electrically connected to the p-type base layer 3, the n⁺-type emitter layer 4, and the p⁺-type semiconductor layer 9. The emitter electrode 17 is insulated from the gate electrode 7 by the first interlayer insulating film 8.

The gate pad 18 is provided via the field insulating film 14 above the conductor 12 formed in the second trench 10. The gate pad 18 is insulated from the conductor 12 by the field insulating film 14 or the second interlayer insulating film 13. The gate pad 18 is electrically connected to a gate wiring (not shown) electrically connected to the gate electrode 7. The gate pad 18 is intended to extract the gate electrode 7 to the outside of the IGBT 100. Like the gate insulating film 6, the field insulating film 14 can be formed from one of e.g. silicon oxide, silicon nitride, silicon oxynitride, and alumina. In this embodiment, the field insulating film 14 is provided independent of the second interlayer insulating film 13. However, it is understood that the insulating film 11 and the second interlayer insulating film 13 can be formed on the surface of the p⁺-type semiconductor layer 9 and the surface of the n⁻-type base layer 2 outside the trench to substitute for the field insulating film 14.

The collector electrode 16, the emitter electrode 17, and the gate pad 18 may be made of an electrode metal material commonly used in the semiconductor process, and can be formed from e.g. aluminum or copper.

The operation of the IGBT 100 according to this embodiment is described. The gate electrode 7 provided in the first trench 5 is subjected to a positive voltage equal to or higher than a threshold relative to the emitter electrode 17. Then, a channel layer is formed in a portion of the p-type base layer 3 adjacent to the gate insulating film 6. When the collector electrode 16 is subjected to a positive voltage relative to the emitter electrode 17, electrons flow from the emitter electrode 17 through the n⁺-type emitter layer 4, the p-type base layer 3, the n⁻-type base layer 2, and the p⁺-type collector layer 15 to the collector electrode 16. Corresponding to these electrons, holes flow from the collector electrode 16 through the p⁺-type collector layer 15, the n⁻-type base layer 2, and the p-type base layer 3 to the emitter electrode 17. At this time, in the n⁻-type base layer 2, holes are excessively accumulated and cause conductivity modulation. Thus, the IGBT 100 turns to low on-resistance.

The conductor 12 provided in the second trench 10 is electrically connected to the gate electrode 7. Thus, the conductor 12 is subjected to the same voltage as the gate electrode 7. That is, the conductor 12 has a gate potential. The p⁺-type semiconductor layer 9 with the second gate trench 10 formed therein is electrically connected to the emitter electrode 17. That is, the p⁺-type semiconductor layer 9 has an emitter potential. Because the second trench 10 is formed in the p⁺-type semiconductor layer 9, the inner wall of the second trench 10 is entirely formed from the p⁺-type semiconductor layer 9. Thus, the conductor 12 formed in the second trench 10, the insulating film 11, and the p⁺-type semiconductor layer 9 form a capacitor. This capacitor constitutes a gate-emitter built-in capacitance C_{ge} of the IGBT 100.

Next, to describe the effect of the IGBT 100 according to this embodiment, the operation of an IGBT of a comparative example is described. The structure of the comparative example is not shown. The IGBT of the comparative example is different from the IGBT 100 according to this embodiment in lacking the p⁺-type semiconductor layer 9, the second trench 10, the insulating film 11, the conductor 12, and the second interlayer insulating film 13. FIG. 2 shows the time variation of collector current I_{c}, collector-emitter voltage V_{ce}, gate-emitter voltage V_{ge}, and turn-on loss Eₒₙ at turn-on of the IGBT of this comparative example. Here, the turn-on loss is defined as power loss due to collector-emitter voltage and collector current during the time from the beginning of the increase of gate-emitter voltage until the collector-emitter voltage is stabilized to zero voltage (hereinafter referred to as the time required for turn-on).

As shown in FIG. 2, the time required for turn-on is composed of T1 and T2. T1 is the time until the gate-emitter voltage reaches the threshold. T2 is the time from the gate-emitter voltage reaching the threshold until the voltage becomes constant by the mirror effect. After the lapse of T2, the gate-emitter voltage starts to increase again and reaches the power supply voltage of the gate driving circuit. As the sum of T1 and T2 becomes larger, the turn-on loss becomes higher. Reduction of turn-on loss requires reducing the sum of T1 and T2.

T1 is proportional to the product of the gate resistance R_{g} and the sum of gate-emitter capacitance C_{ge} and gate-collector capacitance C_{gc}, i.e., (C_{ge}+C_{gc})×R_{g}. T2 is proportional to C_{gc}×R_{g}.

Reduction of both T1 and T2 is desired. However, reduction of T1 results in increasing the variation of collector-emitter voltage, dV_{ce}/dt. As a result, noise is generated in the gate. This makes the IGBT 100 prone to device destruction. Thus, it is desired to reduce T2 with T1 left constant.

Here, T1 can be left constant by increasing the gate-emitter capacitance C_{ge} simultaneously with decreasing the gate resistance R_{g}. Thus, only T2 can be decreased. The IGBT 100 according to this embodiment is different from the IGBT of the comparative example in including a capacitor composed of the conductor 12, the insulating film 11, and the p⁺-type semiconductor layer 9 formed in the second trench 10. Thus, the IGBT 100 according to this embodiment has a large gate-emitter built-in capacitance. Hence, if the gate resistance R_{g} built in the gate driving circuit is decreased with T1 left constant as described above, then in the IGBT 100 according to this embodiment, the time of T2 can be made smaller than in the IGBT of the comparative example.

As the gate-emitter built-in capacitance C_{ge} becomes larger, only T2 can be made smaller with T1 left constant. Thus, in the IGBT 100 according to this embodiment, as the capacitance of the capacitor composed of the conductor 12, the insulating film 11, and the p⁺-type semiconductor layer 9 formed in the second trench 10 (hereinafter referred to as the capacitance of the second trench) becomes larger, the turn-on loss can be made lower.

As described above, one method for increasing the capacitance of the second trench 10 is to form the insulating film 11 of the second trench 10 from a dielectric film having a higher dielectric constant than the gate insulating film 6 formed in the first trench 5. Such a dielectric film can be the aforementioned high-k film made of e.g. hafnium silicate (HfSiO), nitrogen-doped hafnium silicate (HfSiON), nitrogen-doped hafnium aluminate (HfAlON), yttrium oxide (Y₂O₃), or hafnium oxide (HfO₂). In the case where the gate insulating film 6 is made of silicon oxide, the capacitance of the second trench 10 can be increased also by forming the insulating film from silicon nitride or alumina.

Furthermore, the capacitance of the second trench 10 can be increased also by forming the insulating film 11 thinner than the gate insulating film. Naturally, it is also possible to combine thinning of the insulating film and use of a high dielectric film.

As described above, according to this embodiment, the IGBT 100 can have a large gate-emitter built-in capacitance. Thus, the turn-on loss can be reduced without resort to an external capacitor.

In this embodiment, the gate pad 18 is provided via the field insulating film 14 above the conductor 12 formed in the second trench 10. However, this embodiment is not limited above. Instead of the gate pad 18, a diode having a p-n junction or a temperature sensor can be provided via the field insulating film 14 or the second interlayer insulating film 13 above the conductor 12 formed in the second trench 10. Furthermore, the gate pad 18 can be an electrode pad electrically connected to a semiconductor element.

### Second Embodiment

An IGBT 200 according to a second embodiment is described with reference to FIG. 3. FIG. 3 is a main part schematic sectional view of the IGBT 200 according to the second embodiment. The portions having the same configuration as those described in the first embodiment are labeled with like reference numerals or symbols, and the description thereof is omitted. Differences from the first embodiment are primarily described.

The IGBT 200 according to this embodiment includes a device region and a termination region. In this example, the p⁺-type semiconductor layer 9, the second trench 10, the insulating film 11, the conductor 12, and the second interlayer insulating film 13 according to the first embodiment are provided in the termination region of the semiconductor chip.

As shown in FIG. 3, like the IGBT 100 according to the first embodiment, on the first surface side of an n⁻-type base layer 2, the device region includes a first trench 5, a gate insulating film 6, a gate electrode 7, a first interlayer insulating film 8, and an emitter electrode 17. On the second surface side of the n⁻-type base layer 2, the device region includes an n⁺-type buffer layer 1, a p⁺-type collector layer 15, and a collector electrode 16. In the device region, when the IGBT is turned on, a current flows from the collector electrode 16 toward the emitter electrode 17. The termination region surrounds the device region outside the device region, and includes a diced end portion at the outermost edge. On the first surface side of the n⁻-type base layer 2, the termination region includes a p⁺-type semiconductor layer 9, a second trench 10, an insulating film 11, a conductor 12, a second interlayer insulating film 13, a gate wiring layer 19, p⁺-type guard ring layers 20, guard ring metals 21, 22, and a protective film 23. On the second surface side of the n⁻-type base layer 2, the termination region includes the n⁺-type buffer layer 1, the p⁺-type collector layer 15, and the collector electrode 16.

The termination region is composed of two side portions extending along the Y direction and opposed to each other, two side portions extending along the X direction orthogonal thereto and opposed to each other, and four corner portions connecting these side portions at the four corners of the semiconductor chip. The p₊-type semiconductor layer 9 is provided in the termination region so as to be adjacent to the device region around the device region. Like the termination region, the p⁺-type semiconductor layer 9 also includes four corner portions and four side portions. Of the four side portions of the p⁺-type semiconductor layer 9, two opposed side portions are side portions extending along the X direction from one of the corner portions. The two other opposed side portions are two side portions extending along the Y direction from one of the corner portions.

The p⁺-type semiconductor layer 9 is adjacent to the first trench 5 nearest to the termination region, and is provided in the first surface of the n⁻-type base layer 2. The p⁺-type semiconductor layer 9 extends to the second surface side of the n⁻-type base layer 2 farther than the bottom portion of the first trench 5. That is, the bottom portion of the p⁺-type semiconductor layer 9 is deeper than the bottom portion of the first trench 5.

The first trench 5 extends like e.g. a stripe in the Y direction perpendicular to the figure. A plurality of first trenches 5 are arranged in the X direction, which is perpendicular to the Y direction and parallel to the first surface of the n⁻-type base layer 2. As described above, the p⁺-type semiconductor layer 9 is composed of side portions (not shown) extending along the X direction and side portions extending along the Y direction. The p⁺-type semiconductor layer 9 is, in these side portions, a guard ring layer having the function of extending a depletion layer from the device region toward the outside (the end portion side of the semiconductor chip) of the termination region. To achieve this function, the width in the X direction and the Y direction (the horizontal width) of the side portion of the p⁺-type semiconductor layer 9 is made wider as the breakdown voltage becomes higher.

In the first surface of the n⁻-type base layer 2 further outside the p⁺-type semiconductor layer 9, a plurality of p⁺-type guard ring layers 20 spaced from each other are provided so as to surround the p⁺-type semiconductor layer 9. The plurality of p⁺-type guard ring layers 20 have a narrower horizontal width than the p⁺-type semiconductor layer 9.

The second trench 10 extends from the surface of the p⁺-type semiconductor layer 9 into the p⁺-type semiconductor layer 9. The second trenches 10 have a structure of a plurality of stripes extending in the Y direction and arranged in the X direction. In this embodiment, the second trenches 10 have a structure of four stripes arranged in the X direction. The second trench 10 is formed so that the width and the spacing to the adjacent second trench 10 in the X direction are respectively equal to the width and the spacing to the adjacent first trench 5 in the X direction of the first trench 5. Furthermore, the second trench 10 is formed so that the depth of the second trench 10 from the surface of the p⁺-type semiconductor layer 9 is equal to the depth of the first trench 5 from the first surface of the n⁻-type base layer 2. The second trench 10 is integrally formed in the same process as the first trench. However, the second trench 10 is not limited to the above dimensions. Furthermore, the first trench 5 and the second trench 10 may be formed not in the same process.

This embodiment has been described in the case where the above plurality of second trenches are provided in the side portion extending along the Y direction of the p⁺-type semiconductor layer 9. However, the above plurality of second trenches may be formed in the side portion (not shown) extending along the X direction of the p⁺-type semiconductor layer 9. Furthermore, the extending direction of the plurality of second trenches is not limited to the above embodiment, but may be the X direction or Y direction or any other direction in each side portion of the p⁺-type semiconductor layer 9.

The conductor 12 is provided in each of the plurality of second trenches 10 via the insulating film 11. The conductors 12 provided in the plurality of second trenches 10 are electrically connected to each other. In the example of this embodiment, the conductor 12 provided in the plurality of second trenches 10 includes a portion provided via the insulating film 11 on the surface of the p⁺-type semiconductor layer 9. The conductors 12 provided in the adjacent second trenches 10 are electrically connected to each other by this portion. Furthermore, the conductors 12 provided in the plurality of second trenches 10 are electrically connected to the gate electrode 7 provided in the first trench 5.

The second interlayer insulating film 13 is provided so as to cover the conductors 12 provided in the plurality of second trenches 10. In conjunction with the insulating film 11, the second interlayer insulating film 13 insulates the conductors 12 from the surroundings.

The gate wiring layer 19 is provided via the second interlayer insulating film 13 above the conductors 12. The gate wiring layer 19 is electrically connected to the conductors 12 via an opening provided in the second interlayer insulating film 13.

The guard ring metal 21 is provided on the p⁺-type semiconductor layer 9 further outside the gate wiring layer 19 and electrically connected to the p⁺-type semiconductor layer 9. Furthermore, a plurality of other guard ring metals 22 are respectively provided on a plurality of p⁺-type guard ring layers 20 located further outside the p⁺-type semiconductor layer 9. The guard ring metals 22 are electrically connected to the p⁺-type guard ring layers 20.

As in the first embodiment, the emitter electrode 17, the gate wiring layer 19, and the guard ring metals 21, 22 can be formed from aluminum or copper. A protective film 23 is provided thereon and insulates them from each other. The protective film is made of e.g. silicon oxide.

In the IGBT 200 according to this embodiment, the second trenches 10, the insulating film 11, and the conductors 12 are formed in the p⁺-type semiconductor layer 9 formed in the side portion extending along the Y direction of the termination region. In order to function as a guard ring layer, the p⁺-type semiconductor layer 9 has a structure extending from the device region toward the outside of the termination region. As the p⁺-type semiconductor layer 9 extends farther outward, the breakdown voltage of the IGBT 200 becomes higher. Thus, a higher breakdown voltage of the IGBT 200 requires a larger area of the p⁺-type semiconductor layer 9 occupied in the semiconductor chip.

Hence, in the IGBT 200 according to this embodiment, the capacitance of the second trench can be made higher than in the first embodiment without forming any additional ineffective region in the semiconductor chip. In particular, the second trenches 10 are formed in a plurality in the p⁺-type semiconductor layer 9. This increases the area of the insulating film 11 sandwiched between the conductor 12 and the p⁺-type semiconductor layer 9. Thus, the capacitance of the second trenches 10 can be increased.

In this embodiment, the second trenches 10 have a structure of four stripes. However, the spacing between the adjacent second trenches 10 can be made narrower than the spacing between the adjacent first trenches 5 so that more second trenches can be formed. This can further increase the capacitance of the second trenches.

This embodiment has been described in the case where the second trenches have a structure of a plurality of stripes extending in the Y direction perpendicular to the page. However, the embodiment is not limited thereto. The second trenches can have a structure such as lattice structure, staggered lattice structure, or honeycomb structure further including a plurality of connection trenches extending along the X direction orthogonal to the Y direction and connected to the adjacent second trench.

This embodiment has been described in the case where the p⁺-type semiconductor layer 9, the second trench 10, the insulating film 11, and the conductor 12 are formed in the side portion along the Y direction of the termination region. However, as described above, they can be similarly formed in the side portion along the X direction of the termination region.

As described above, the IGBT 200 according to this embodiment includes a capacitance of second trenches formed from the p⁺-type semiconductor layer 9, the second trench 10, the insulating film 11, and the conductor 12 in the termination region. Thus, the IGBT 200 can have a higher gate-emitter built-in capacitance without including any additional ineffective region.

### Third Embodiment

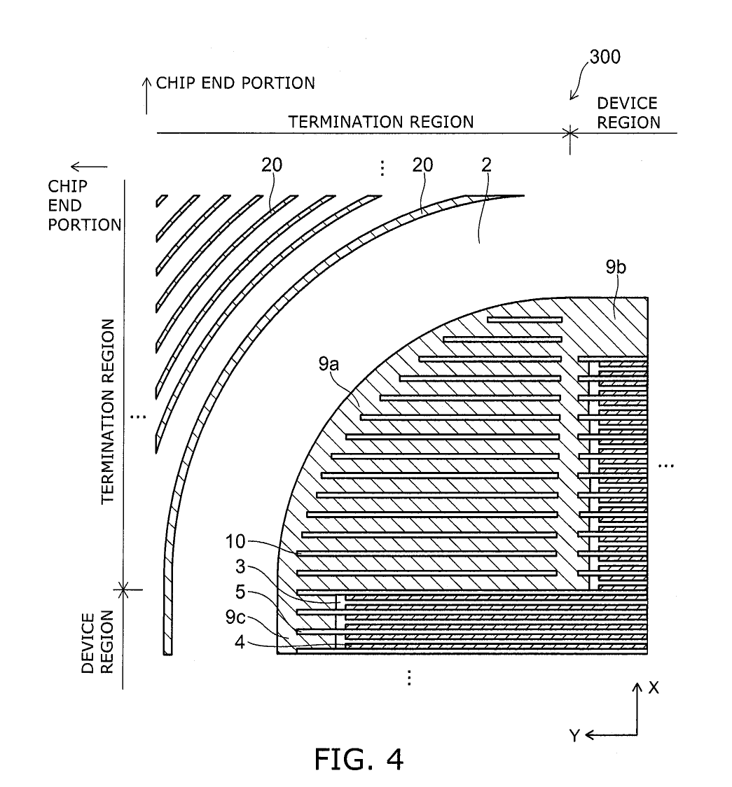

An IGBT 300 according to a third embodiment is described with reference to FIG. 4. FIG. 4 is a main part schematic top view of the IGBT 300 according to the third embodiment. The portions having the same configuration as those described in the second embodiment are labeled with like reference numerals or symbols, and the description thereof is omitted. Differences from the second embodiment are primarily described.

FIG. 4 shows a planar pattern of the corner portion of the termination region on the first surface of the n⁻-type base layer 2 in the IGBT 300 according to this embodiment. The details of the structure in the first trench 5 and the second trench 10 are similar to those of the above embodiments, and hence not shown. The emitter electrode 17, the first interlayer insulating film 8, the second interlayer insulating film 13, the gate wiring layer 19, the guard ring metals 21, 22, the protective film 23 and the like provided on the first surface of the n⁻-type base layer 2 are not shown.

As shown in FIG. 4, as in the second embodiment, a plurality of first trenches 5 extending in the Y direction and arranged in the X direction are formed in the device region. As in the second embodiment, a p-type base layer 3 and an n⁺-type emitter layer 4 are provided between each adjacent pair of the plurality of first trenches. A plurality of p-type base layers 3 and a plurality of n⁺-type emitter layers 4 extend in the Y direction along the first trenches.

Outside the device region, a termination region is provided so as to surround the device region as in the second embodiment. That is, the termination region is composed of four side portions and four corner portions connecting the side portions at the four corners.

In the corner portion of the termination region, outside portions of the plurality of first trenches provided in the device region are set back toward the inside of the device region along the Y direction. Thus, a recess is formed in the device region. In other words, outside portions of the plurality of p-type base layers 3 provided in the device region are set back toward the inside of the device region along the Y direction. Thus, a recess is formed in the device region. In still other words, in the corner portion of the device region, outside portions in the X direction of the plurality of first trenches and outside portions in the X direction of the plurality of p-type base layers 3 provided in the device region do not reach the corner portion of the device region along the Y direction. Thus, a recess is formed in the corner portion of the device region.

In this recess of the device region, the corner portion 9a of the p⁺-type semiconductor layer 9 is provided and adjacent to the device region. The side portion 9b of the p⁺-type semiconductor layer 9 extending along the Y direction extends from the corner portion 9a of the p⁺-type semiconductor layer 9 while being adjacent to the device region along the Y direction (i.e., adjacent to the first trench 5), and reaches a corner portion 9a of the p⁺-type semiconductor layer 9 on the opposite side. This opposite corner portion 9a of the p⁺-type semiconductor layer 9 is also similarly provided in a recess of the device region.

The side portion 9c of the p⁺-type semiconductor layer 9 extending along the X direction extends from the aforementioned corner portion 9a of the p⁺-type semiconductor layer 9 while being adjacent to the device region along the X direction (i.e., adjacent to the tips of a plurality of p-type base layers 3 and a plurality of first trenches), and reaches another corner portion 9a of the p⁺-type semiconductor layer 9 on the opposite side. The other opposite corner portion 9a of the p⁺-type semiconductor layer 9 is also similarly provided in a recess of the device region.

The device region is surrounded with the corner portions 9a of the p⁺-type semiconductor layer 9, the side portions 9b extending along the Y direction, and the side portions 9c extending along the X direction described above. As in the second embodiment, the p⁺-type semiconductor layer 9 functions as a guard ring layer. Further outside (on the semiconductor chip end portion side of) the p⁺-type semiconductor layer 9, a plurality of p⁺-type guard ring layers 20 spaced from each other are provided so as to surround the p⁺-type semiconductor layer 9. The plurality of p⁺-type guard ring layers 20 have a narrower width in the X direction and the Y direction than the p⁺-type semiconductor layer 9.

A plurality of second trenches 10 are provided in the corner portion 9a of the p⁺-type semiconductor layer 9. The plurality of second trenches extend like stripes in the Y direction and are arranged along the X direction. The corner portion 9a of the p⁺-type semiconductor layer 9 is shaped like a quadrant. The edge of the corner portion 9a of the p⁺-type semiconductor layer 9 on the opposite side from the device region is shaped like a circular arc. The plurality of second trenches 10 are all contained inside the corner portion 9a of the p⁺-type semiconductor layer 9. In this embodiment, the plurality of second trenches 10 are as many as the first trenches 5 adjacent to the recess of the device region in the Y direction. On the extension line of this first trench 5, the second trench 10 extends in the Y direction. The plurality of second trenches 10 are also similarly provided in the other corner portions 9a of the p⁺-type semiconductor layer 9.

In this embodiment, the plurality of second trenches 10 have a structure of stripes extending along the Y direction. However, the plurality of second trenches 10 may have a structure of stripes extending along the X direction and arranged along the Y direction.

In the IGBT 300 according to this embodiment, the corner portion 9a of the p⁺-type semiconductor layer 9 is formed in the recess of the device region provided in the corner portion of the termination region. In this corner portion 9a of the p⁺-type semiconductor layer 9, the second trenches 10, the insulating film 11, and the conductors 12 are formed. A higher breakdown voltage of the IGBT 300 requires a larger area of the corner portion 9a of the p⁺-type semiconductor layer 9. Thus, as the breakdown voltage of the IGBT 300 becomes higher, more second trenches can be formed in the corner portion 9a of the p⁺-type semiconductor layer 9. This can increase the capacitance of the second trenches 10.

The area of the corner portion 9a of the p+-type semiconductor layer 9 occupied in the semiconductor chip is larger than the area of the side portions 9b of the p⁺-type semiconductor layer 9 occupied in the semiconductor chip. Thus, the IGBT 300 according to this embodiment can have a higher gate-emitter built-in capacitance without including any additional ineffective region than the IGBT 200 according to the second embodiment.

In this embodiment, compared with the first trench 5 adjacent in the Y direction to the corner portion 9a of the p⁺-type semiconductor layer 9, the first trench 5 adjacent in the Y direction to the side portion 9c extending in the X direction of the p⁺-type semiconductor layer 9 has a larger amount of protrusion in the Y direction from the p-type base layer 3 toward the end portion of the semiconductor chip. The portion of the first trench 5 protruding to the side portion 9c extending in the X direction of the p⁺-type semiconductor layer 9 can be regarded as a second trench 10. That is, in the side portion 9c extending in the X direction of the p⁺-type semiconductor layer 9, there is a second trench 10 continuing to the first trench 5. This can also be regarded as the reason that the IGBT 300 according to this embodiment has a high gate-emitter built-in capacitance.

### Fourth Embodiment

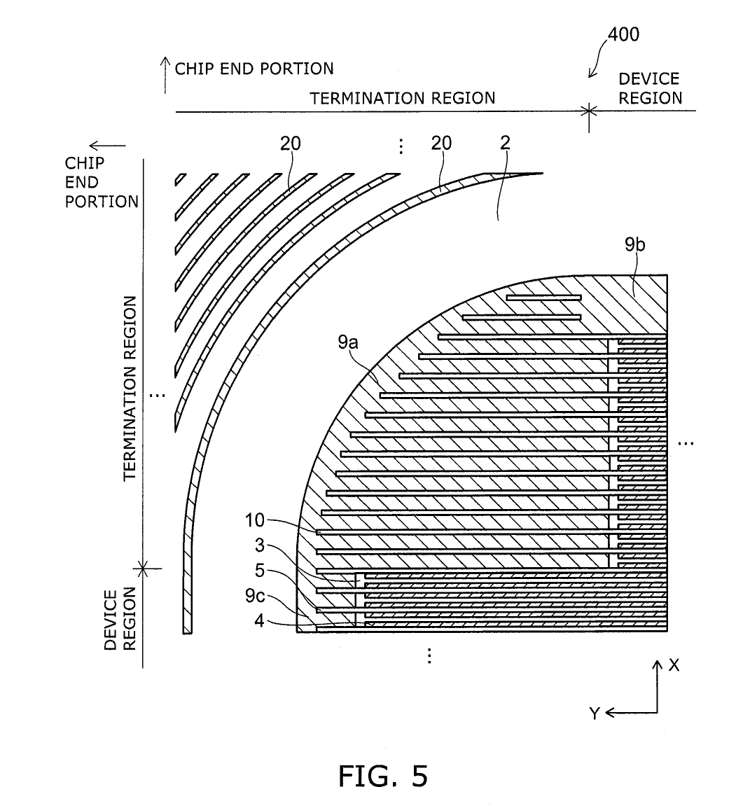

An IGBT 400 according to a fourth embodiment is described with reference to FIG. 5. FIG. 5 is a main part schematic top view of the IGBT 400 according to the fourth embodiment. The portions having the same configuration as those described in the third embodiment are labeled with like reference numerals or symbols, and the description thereof is omitted. Differences from the third embodiment are primarily described.

The IGBT 400 according to this embodiment has a structure in which the first trench 5 and the second trench 10 are integrally joined in the corner portion 9a of the p⁺-type semiconductor layer 9 of the IGBT 300 according to the third embodiment. The effect according to this embodiment is almost the same as the effect according to the third embodiment.

### Fifth Embodiment

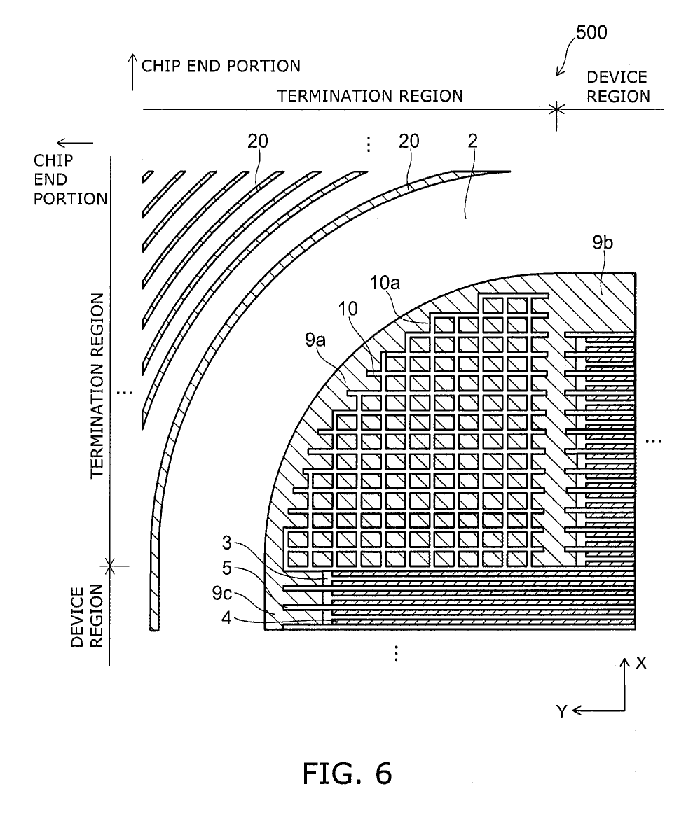

An IGBT 500 according to a fifth embodiment is described with reference to FIG. 6. FIG. 6 is a main part schematic top view of the IGBT 500 according to the fifth embodiment. The portions having the same configuration as those described in the third embodiment are labeled with like reference numerals or symbols, and the description thereof is omitted. Differences from the third embodiment are primarily described.

The IGBT 500 according to this embodiment is different from the IGBT 300 according to the third embodiment in that adjacent second trenches of a plurality of second trenches 10 include a plurality of connection trenches 10a connecting the adjacent second trenches in the X direction. That is, in the IGBT 500, in the corner portion 9a of the p⁺-type semiconductor layer 9, the plurality of second trenches 10 are formed like a lattice so as to extend in the X direction and the Y direction. The conductor 12 is formed like a lattice in these lattice-shaped second trenches via the insulating film 11. The second trenches are not limited to the lattice shape, but can be shaped like a staggered lattice or honeycomb.

The effect according to this embodiment is almost the same as the effect according to the third embodiment.

### Sixth Embodiment

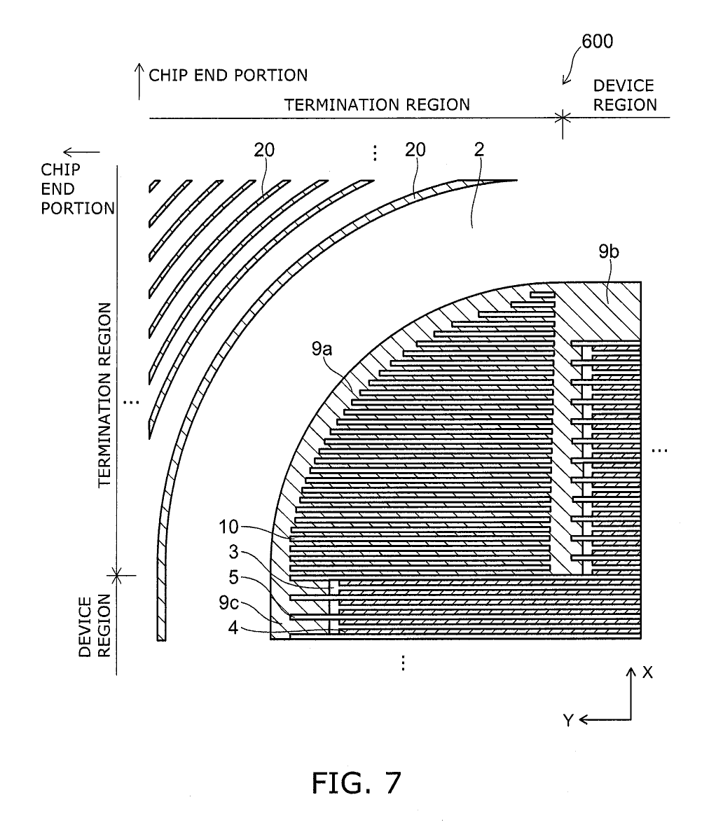

An IGBT 600 according to a sixth embodiment is described with reference to FIG. 7. FIG. 7 is a main part schematic top view of the IGBT 600 according to the sixth embodiment. The portions having the same configuration as those described in the third embodiment are labeled with like reference numerals or symbols, and the description thereof is omitted. Differences from the third embodiment are primarily described.

The IGBT 600 according to this embodiment is different from the IGBT 300 according to the third embodiment in that between the plurality of second trenches 10, a second trench is further provided. That is, the pitch in the X direction of the plurality of second trenches 10 of the IGBT 600 according to this embodiment is half the pitch of the plurality of second trenches 10 of the IGBT 300 according to the third embodiment. In the IGBT 600 according to this embodiment, compared with the IGBT 300 according to the third embodiment, the total area of the insulating film 11 formed on the inner wall surface of the second trenches is approximately twice as large. Thus, the IGBT 600 according to this embodiment has a higher emitter-gate built-in capacitance than the IGBT 300 according to the third embodiment.

The pitch in the X direction of the plurality of second trenches 10 is not limited to the foregoing. The pitch in the X direction of the plurality of second trenches 10 only needs to be shorter than the pitch in the X direction of the plurality of first trenches 5. Alternatively, the spacing in the X direction between the plurality of second trenches 10 only needs to be narrower than the spacing in the X direction between the plurality of first trenches 5.

### Seventh Embodiment

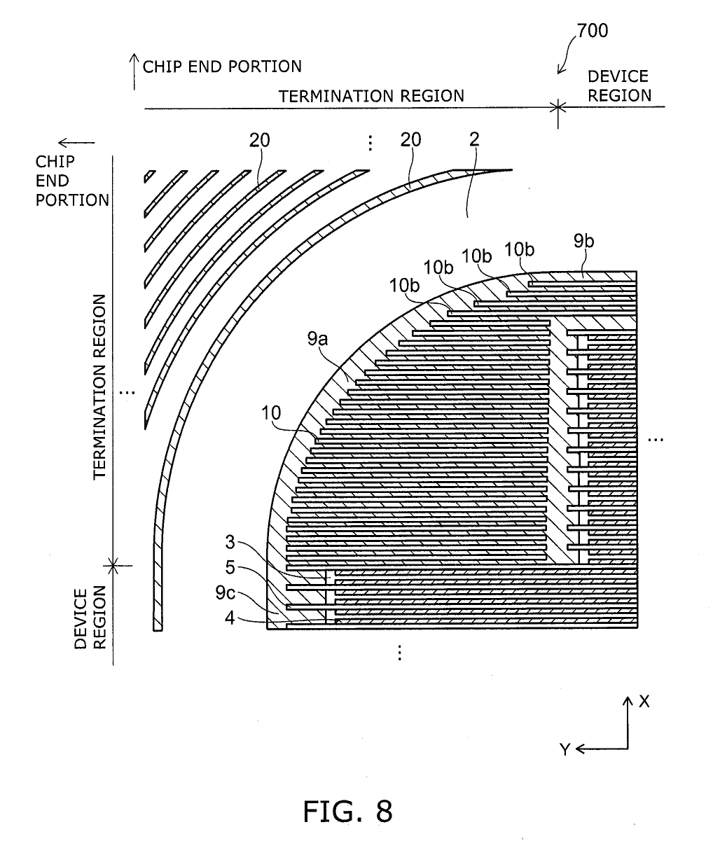

An IGBT 700 according to a seventh embodiment is described with reference to FIG. 8. FIG. 8 is a main part schematic top view of the IGBT 700 according to the seventh embodiment. The portions having the same configuration as those described in the sixth embodiment are labeled with like reference numerals or symbols, and the description thereof is omitted. Differences from the sixth embodiment are primarily described.

As shown in FIG. 8, the IGBT 700 according to this embodiment is different from the IGBT 600 according to the sixth embodiment in having a structure in which a subset 10b of the plurality of second trenches 10 extends into the side portion 9b extending along the Y direction from the corner portion 9a of the p⁺-type semiconductor layer 9. Alternatively, besides the plurality of second trenches in the corner portion 9a of the p⁺-type semiconductor layer 9, the IGBT 700 according to this embodiment may include a plurality of other second trenches (not shown) in the side portion 9b of the p⁺-type semiconductor layer 9 extending along the Y direction.

Furthermore, the IGBT 700 may include a plurality of still other second trenches (not shown) in the side portion 9c of the p⁺-type semiconductor layer 9 extending along the X direction.

The aforementioned plurality of other second trenches 10, not shown, provided in the side portion 9b extending along the Y direction and the side portion 9c extending along the X direction of the p⁺-type semiconductor layer 9 are not limited to those extending along the Y direction as shown in FIG. 8, but may extend along the X direction.

The IGBT 700 according to this embodiment has a higher emitter-gate built-in capacitance than the IGBT 600 according to the sixth embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device comprising:
a first semiconductor layer of a first conductivity type having a first surface and a second surface on opposite side from the first surface and including a first trench extending from the first surface toward the second surface;
a second semiconductor layer of a second conductivity type provided in the first surface of the first semiconductor layer, being adjacent to the first trench, and exposed at a sidewall of the first trench;
a third semiconductor layer of the first conductivity type selectively provided in a surface of the second semiconductor layer, being adjacent to the first trench, and exposed at the sidewall of the first trench;
a fourth semiconductor layer of the second conductivity type extending from the first surface of the first semiconductor layer to the second surface side farther than the first trench;
a gate electrode provided via a gate insulating film on the first semiconductor layer, on the second semiconductor layer, and on the third semiconductor layer in the first trench;
a conductor provided via an insulating film on the fourth semiconductor layer in a second trench extending from a surface of the fourth semiconductor layer into the fourth semiconductor layer, the conductor being electrically connected to the gate electrode;
a first interlayer insulating film provided on the gate electrode;
a second interlayer insulating film provided on the conductor;
a first electrode electrically connected to the second surface of the first semiconductor layer; and
a second electrode electrically connected to the second semiconductor layer, the third semiconductor layer, and the fourth semiconductor layer and insulated from the gate electrode by the first interlayer insulating film.

2. The device according to claim 1, further comprising:
a gate wiring layer provided via the second interlayer insulating film on the conductor on the first surface side of the first semiconductor layer and electrically connected to the gate electrode.

3. The device according to claim 1, wherein
the device includes:
a device region provided in the first surface of the first semiconductor layer and including a plurality of unit structures along a first direction parallel to the first surface of the first semiconductor layer, the unit structure including the first trench, the gate insulating film, the gate electrode, the first interlayer insulating film, the second semiconductor layer, and the third semiconductor layer; and
a termination region surrounding an outer periphery of the device region and including the fourth semiconductor layer, the second trench, the insulating film, the conductor, and the second interlayer insulating film,
the plurality of first trenches and the plurality of second semiconductor layers extend in a second direction perpendicular to the first direction and parallel to the first surface,
in a corner portion of the device region, outside portions of the plurality of first trenches and outside portions of the plurality of second semiconductor layers do not reach the corner portion of the device region along the second direction so that the corner portion of the device region includes a recess,
the fourth semiconductor layer includes a first portion adjacent to the device region in the recess of the device region, and
the second trench is provided in the first portion.

4. The device according to claim 3, wherein the second trench extends along the second direction and is provided in a plurality along the first direction.

5. The device according to claim 4, wherein the fourth semiconductor layer further includes a second portion extending along the second direction from the first portion and being adjacent to the device region, and
a subset of the plurality of second trenches extends along the second direction in the second portion of the fourth semiconductor layer.

6. The device according to claim 4, wherein spacing between the plurality of second trenches is narrower than spacing between the plurality of first trenches.

7. The device according to claim 4, wherein the plurality of second trenches are provided on extension lines of the plurality of first trenches.

8. The device according to claim 7, wherein the plurality of second trenches continue to the plurality of first trenches.

9. The device according to claim 4, wherein adjacent ones of the plurality of second trenches include a plurality of connection trenches connecting the adjacent second trenches in the first direction.

10. The device according to claim 1, comprising:
a diode provided via the second interlayer insulating film on the conductor on the first surface side of the first semiconductor layer and including a junction of the first conductivity type and the second conductivity type.

11. The device according to claim 1, comprising:
a temperature sensor provided via the second interlayer insulating film on the conductor on the first surface side of the first semiconductor layer.

12. The device according to claim 1, further comprising:
a semiconductor element,
wherein an electrode pad electrically connected to the semiconductor element is provided via the second interlayer insulating film on the conductor on the first surface side of the first semiconductor layer.

13. The device according to claim 1, wherein the insulating film has a higher dielectric constant than the gate insulating film.

14. The device according to claim 1, wherein the insulating film has a thinner film thickness than the gate insulating film.

15. The device according to claim 1, further comprising:
a fifth semiconductor layer of the second conductivity type between the first semiconductor layer and the first electrode.

16. The device according to claim 1, wherein the first semiconductor layer, the second semiconductor layer, the third semiconductor layer, and the fourth semiconductor layer are made of silicon carbide or nitride semiconductor.

17. A power semiconductor device comprising:
a first semiconductor layer of a first conductivity type having a first surface and a second surface on opposite side from the first surface and including a first trench extending from the first surface toward the second surface;
a second semiconductor layer of a second conductivity type provided in the first surface of the first semiconductor layer, being adjacent to the first trench, and exposed at a sidewall of the first trench;
a third semiconductor layer of the first conductivity type selectively provided in a surface of the second semiconductor layer, being adjacent to the first trench, and exposed at the sidewall of the first trench;
a fourth semiconductor layer of the second conductivity type extending from the first surface of the first semiconductor layer to the second surface side farther than the first trench;
a gate electrode provided via a gate insulating film on the first semiconductor layer, on the second semiconductor layer, and on the third semiconductor layer in the first trench;
a conductor provided via an insulating film on the fourth semiconductor layer in a second trench extending from a surface of the fourth semiconductor layer into the fourth semiconductor layer, the conductor being electrically connected to the gate electrode;
a first interlayer insulating film provided on the gate electrode;
a second interlayer insulating film provided on the conductor;
a first electrode electrically connected to the second surface of the first semiconductor layer;
a second electrode electrically connected to the second semiconductor layer, the third semiconductor layer, and the fourth semiconductor layer and insulated from the gate electrode by the first interlayer insulating film;
a gate wiring layer provided via the second interlayer insulating film on the conductor on the first surface side of the first semiconductor layer and electrically connected to the gate electrode; and
a fifth semiconductor layer of the second conductivity type between the first semiconductor layer and the first electrode,
the device including:
a device region provided in the first surface of the first semiconductor layer and including a plurality of unit structures along a first direction parallel to the first surface of the first semiconductor layer, the unit structure including the first trench, the gate insulating film, the gate electrode, the first interlayer insulating film, the second semiconductor layer, and the third semiconductor layer; and
a termination region surrounding an outer periphery of the device region and including the fourth semiconductor layer, the second trench, the insulating film, the conductor, and the second interlayer insulating film,
the plurality of first trenches and the plurality of second semiconductor layers extending in a second direction perpendicular to the first direction and parallel to the first surface,
in a corner portion of the device region, outside portions of the plurality of first trenches and outside portions of the plurality of second semiconductor layers not reaching the corner portion of the device region along the second direction so that the corner portion of the device region includes a recess,
the fourth semiconductor layer including a first portion adjacent to the device region in the recess of the device region and a second portion extending along the second direction from the first portion and being adjacent to the device region,
the second trench being provided in the first portion, extending along the second direction, and being provided in a plurality along the first direction,
a subset of the plurality of second trenches extending along the second direction in the second portion of the fourth semiconductor layer,
spacing between the plurality of second trenches being narrower than spacing between the plurality of first trenches,
adjacent ones of the plurality of second trenches including a plurality of connection trenches connecting the adjacent second trenches in the first direction,
the insulating film having a higher dielectric constant than the gate insulating film, and
the insulating film having a thinner film thickness than the gate insulating film.
